(19) United States
(12) Patent Application Publication
(10) Pub. No.: US 2010/0164044 A1
(43) Pub. Date: Jul. 1, 2010

(54) IMAGE SENSOR AND MANUFACTURING METHOD THEREOF

(76) Inventor: Chang-Eun Lee, Mapo-gu (KR)

Correspondence Address: SHERR & VAUGHN, PLLC, 620 HERNDON PARKWAY, SUITE 320, HERNDON, VA, 20170, US

(21) Appl. No.: 12/646,594

(22) Filed: Dec. 23, 2009

(30) Foreign Application Priority Data
Dec. 30, 2008 (KR) 10-2008-0136260

(51) Int. Cl. H01L 27/146; H01L 31/18

(52) U.S. Cl. 257/443; 438/80; 257/E27.133; 257/E21.328

(57) ABSTRACT

An image sensor includes first to fourth image sensing sections symmetrically aligned in a form of a 2×2 matrix, first to fourth pixel arrays aligned in the first to fourth image sensing sections, respectively, in adjacent to each other, and first to fourth peripheral circuit parts aligned at peripheral portions of the first to fourth image sensing sections. A middle-size CMOS image sensor is provided that is suitable for the available field size of conventional photo equipment, so the manufacturing cost may be minimized and price competitiveness may be maximized while providing high-quality images with high pixel resolution.

The present application claims priority under 35 U.S.C. 119 to Korean Patent Application No. 10-2008-0136260 (filed on Dec. 30, 2008), which is hereby incorporated by reference in its entirety.

### BACKGROUND

In general, image sensors are semiconductor devices to convert an optical image into an electrical signal. CMOS (Complementary Metal Oxide Silicon) image sensors are spotlighted as next-generation image sensors. A CMOS image sensor is a device employing a switching mode to sequentially detect an output of each unit pixel by means of MOS transistors, in which the MOS transistors are formed on a semiconductor substrate corresponding to the unit pixels through a CMOS technology using peripheral devices, such as a controller and a signal processor. The CMOS image sensor includes a photodiode and the MOS transistor in each unit pixel, and sequentially detects electric signals of each unit pixel in a switching mode to realize images.

Since the CMOS image sensor is manufactured by utilizing the CMOS technique, it has an advantage of low power consumption. In addition, since a smaller number of photo-processing steps are required, the manufacturing process of the CMOS image sensor can be simplified. Further, since a controller, a signal processor, an analog/digital converter, and the like can be integrated on a CMOS image sensor chip, the CMOS image sensor can minimize the size of a product. Accordingly, the CMOS image sensor is widely applied to various application fields, such as a digital still camera, a digital video camera, etc.

### SUMMARY

Embodiments relate to a CMOS image sensor having a middle-size format suitable for an available field size of photo equipment. Embodiments relate to a CMOS image sensor capable of producing a middle-size or a large-size CMOS image without exchanging expensive equipment while realizing relatively high pixel resolution and enlarging an imaging plane.

An image sensor according to embodiments may include first to fourth image sensing sections symmetrically aligned in a form of a 2×2 matrix, first to fourth pixel arrays aligned in the first to fourth image sensing sections, respectively, adjacent to each other, and first to fourth peripheral circuit parts aligned at peripheral portions of the first to fourth image sensing sections.

An image sensor according embodiments may include first and second image sensing sections, first and second pixel arrays aligned adjacent to each other at a boundary between the first and second image sensing sections, and first and second peripheral circuit parts aligned at peripheral portions of the first and second image sensing sections.

A method of manufacturing an image sensor according to embodiments includes forming first to fourth masks, in which the second to fourth masks are formed by sequentially turning over the first mask, aligning the first to fourth masks on a wafer, and exposing first to fourth dies, which are adjacent to each other on the wafer, through the first to fourth masks.

A method of manufacturing an image sensor according to embodiments includes preparing a mask including a first mask pattern formed on and/or over a top surface of a substrate and a second mask pattern formed on and/or over a bottom surface of the substrate, performing a first photo process on a first image sensing section by using the first mask pattern of the mask, performing a second photo process on a third image sensing section by transversely rotating the mask at an angle of 180°, performing a third photo process on a second image sensing section by using the second mask pattern of the mask, and performing a fourth photo process on a fourth image sensing section by transversely rotating the mask at an angle of 180°.

A method of manufacturing an image sensor according to embodiments includes forming first and second masks, in which the second mask is formed by turning over the first mask; aligning the first and second masks on a wafer; and exposing first and second dies, which are adjacent to each other on the wafer, through the first and second masks.

A method of manufacturing an image sensor according to embodiments includes preparing a mask including a first mask pattern formed on and/or over a top surface of a substrate and a second mask pattern formed on and/or over a bottom surface of the substrate, performing a first photo process on a first image sensing section by using the first mask pattern of the mask, and performing a second photo process on a second image sensing section by using the second mask pattern of the mask.

### DRAWINGS

FIG. 1 is a plane view of a CMOS image sensor.

FIG. 2 is a plan view of an image sensor according to embodiments.

FIG. 3 is a plan view of an image sensor according to embodiments.

FIG. 4 is a view showing masks for manufacturing an image sensor, such as the sensor shown in FIG. 3.

FIGS. 5 and 6 are perspective and sectional views showing other masks for manufacturing an image sensor, such as the sensor shown in FIG. 3.

FIG. 7 is a plan view of an image sensor according to embodiments.

FIG. 8 is a plan view showing masks for manufacturing an image sensor, such as the sensor shown in FIG. 7.

### DESCRIPTION

Hereinafter, an image sensor and a manufacturing method thereof according to embodiments will be described in detail with reference to accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, and one or more intervening layers may also be present. In addition, it will also be understood that when a layer is referred to as being ‘between’ two layers, it can be the only layer between the two layers, or one or more intervening layers may also be present.

The size or thickness of elements or layers shown in the drawings may be magnified, omitted or schematically shown for the purpose of clear explanation and the real size of the elements or the layers may be different from the size of elements shown in drawings.

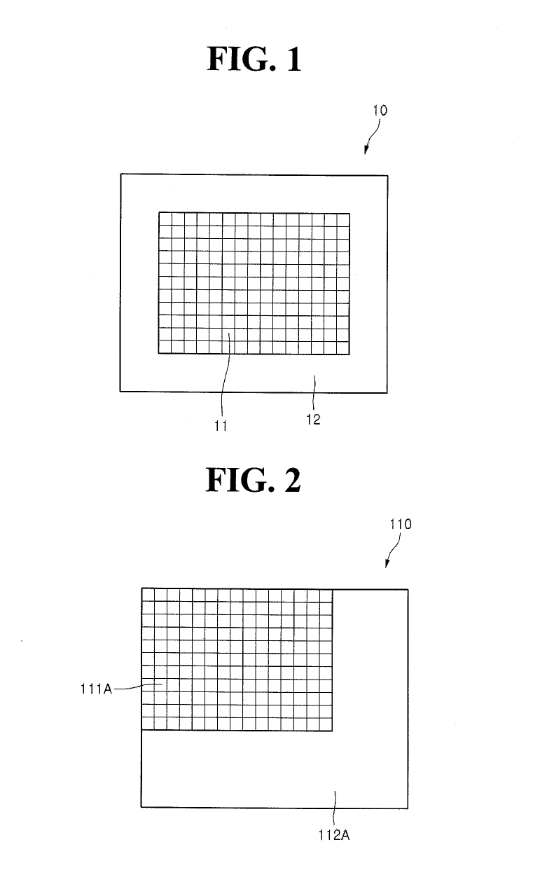

CMOS image sensors can be classified into a 3T CMOS image sensor having three transistors, a 4T CMOS image sensor having four transistors, and a 5T CMOS image sensor having five transistors according to the number of transistors. FIG. 1 is a plan view showing a CMOS image sensor.

Referring to FIG. 1, an image sensor 10 includes a light receiving section 11, which receives light to convert an optical signal into an electric signal, and a peripheral circuit section 12, which processes the signal generated from the light receiving section 11 and then transfers the signal to the light receiving section 11. However, an available maximum field size of photo equipment, which determines the size of the light receiving section 11 of the image sensor 10, may be restricted to 25 mm×35 mm, so a CMOS image sensor having a normal film size of 36 mm×24 mm or more may not be realized through the semiconductor process. A middle-size film camera has a FOV (Field of View) greater than that of a normal 35 mm film. A middle-size film camera has a large-size image plane and high pixel resolution, so it can produce high quality pictures. Thus, a middle-size film camera represents superior image quality and color sense in a large-size print and commercial use as compared with the normal film camera. For this reason, a middle-size film camera is utilized in various fields where commercial pictures and high-quality products are required. Typically, a middle-size film camera can have various film sizes of 6×6, 6×7, 6×45, and 6×12. However, the above film sizes result in large field sizes, so that the CMOS image sensor fabricated through the normal semiconductor process may not be suitable for the middle-size film camera because the field size of one die is restricted.

FIG. 2 is a plan view of an image sensor according to embodiments. FIG. 2 shows a first image sensing section 110 in a CMOS image sensor including four dies. The first image sensing section 110 includes a first pixel array part 111A formed at an edge of one die among plural dies formed on a wafer and a first peripheral circuit part 112A formed at a peripheral portion of the first pixel array part 111A.

The image sensor includes four dies to form a middle-size format product. In other words, one die corresponds to ¼ field of the image sensor. The first pixel array part 111A of the first image sensing section 110 is a light receiving area that receives light and generates a signal by using the light. The first peripheral circuit part 112A is a logic circuit area that transmits the signal to the first pixel array part 111A. Transistors are formed in the logic circuit to process signals generated from the pixel array part 111A. The first pixel array part 111A may include a pixel array having a plurality of pixels aligned in the form of a matrix. Each pixel includes at least one photodiode area and transistors for processing photonic electrons generated from the photodiode area.

The first pixel array part 111A is provided at a rectangular region including two adjacent edges of a rectangular diode. The first peripheral circuit part 112A is provided at a region including two adjacent edges of the first pixel array part 111A.

Second to fourth image sensing sections can be formed by using a pattern design of the first image sensing section 110 without separately designing the second to fourth image sensing sections. For instance, the second image sensing section can be formed by symmetrically turning over the pattern of the first image sensing section upward, the third image sensing section can be formed by symmetrically turning over the pattern of the second image sensing section leftward, and the fourth image sensing section can be formed by symmetrically turning over the pattern of the third image sensing section downward. That is, if the mask pattern for the ¼ field area of the image sensor is designed, mask patterns for remaining ¾ field areas of the image sensor can be obtained by turning over the original mask pattern upward, downward, leftward and rightward. Therefore, the mask pattern can be easily designed and the mask can be simply manufactured, so that the product yield is maximized and the manufacturing cost is minimized.

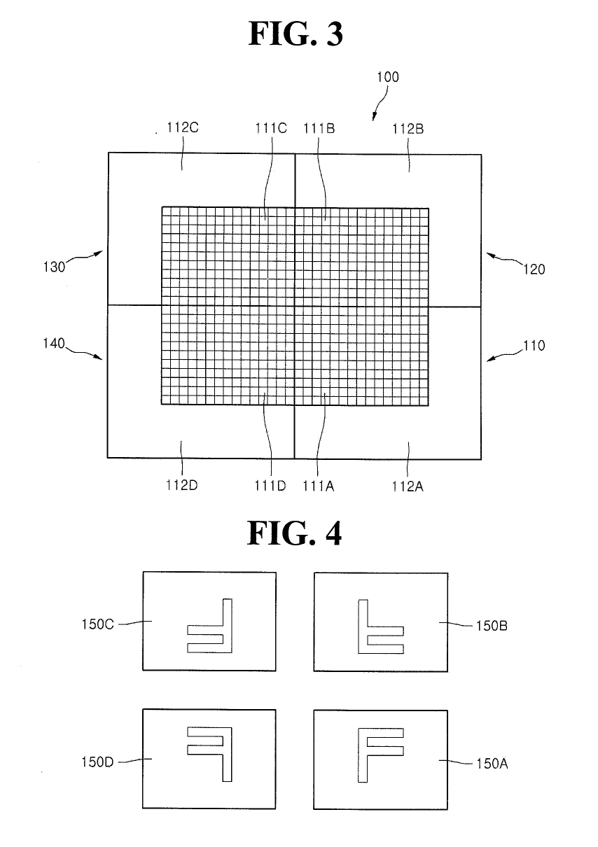

FIG. 3 is a plan view showing the image sensor according to embodiments. Referring to FIG. 3, an image sensor 100 may include first to fourth image sensing sections 110, 120, 130 and 140, in which second to fourth image sensing sections 120, 130 and 140 are formed by turning over the first image sensing section 110.

The first image sensing section 110 includes the first pixel array part 111A and the first peripheral circuit part 112A. The second image sensing section 120 includes a second pixel array part 111B and a second peripheral circuit part 112B. The third image sensing section 130 includes a third pixel array part 111C and a third peripheral circuit part 112C. The fourth image sensing section 140 includes a fourth pixel array part 111D and a fourth peripheral circuit part 112D.

The first to fourth pixel array parts 111A to 111D may be aligned at the center of the image sensor 100, and the first to fourth peripheral circuit parts 112A to 112D may be aligned at peripheral area of the image sensor 100 while surrounding the first to fourth pixel array parts 111A to 111D. The first to fourth pixel array parts 111A to 111D constitute a light receiving section which receives light to generate a signal in the image sensor 100.

In a single wafer, the first to fourth image sensing sections 110 to 140 may be aligned on four adjacent dies, respectively. Patterns of the second to fourth image sensing sections can be obtained by sequentially turning over the pattern of the first image sensing section 110 upward, leftward and downward. That is, four mask patterns may be formed in a single wafer by symmetrically forming four masks in the CMOS image sensor.

According to the chip design of the CMOS image sensor, row/column readout can be separately performed in the peripheral circuit part. In addition, the signal can be separately transmitted to an A/D (analog/digital) converter. Various signal processing sections or an ISP (image signal processor) is provided in a camera module.

After manufacturing the middle-size format image sensor, the image sensor may be packaged such that the image sensor is connected to the ISP of the camera module through a wire, so that the signal processing is possible. Thus, although the four adjacent dies are individually fabricated, they can simultaneously operate.

A CMOS image sensor is manufactured through the above process, provides a middle-size image sensor suitable for the field size of photo equipment. Since there is substantially no space among the first to fourth pixel array parts 111A to 111D, a high-quality image can be realized. That is, the first to fourth pixel array parts 111A to 111D can be directly or closely connected to each other at boundary areas therebetween.

According to embodiments, a large-size CIS having ultra high pixel resolution and a field size above 36 mm×24 mm of a normal film camera can be obtained. According to embodiments, in order to form one pattern in the first to fourth image sensing sections 110 to 140, four masks may be used for the first to fourth image sensing sections 110 to 140. The four masks can be manufactured by sequentially turning over the pattern of the first image sensing section upward, leftward and downward.

For instance, in order to form gate electrodes of the first to fourth image sensing sections 110 to 140, the pattern of the first image sensing section 110 is primarily designed. Then, the patterns of the second to fourth image sensing sections 120 to 140 can be obtained by sequentially turning over the pattern of the first image sensing section upward, leftward and downward. After that, mask patterns for forming the gate electrodes of the first to fourth image sensing sections 110 to 140 can be designed and manufactured.

FIG. 4 is a view showing masks for manufacturing an image sensor, such as the sensor shown in FIG. 3. In order to form the patterns of the first to fourth image sensing sections 110 to 140, first to fourth masks 150A to 150D are prepared. The second mask 150B can be obtained by symmetrically turning over the first mask 150A upward, the third mask 150C can be obtained by symmetrically turning over the second mask 150B leftward, and the fourth mask 150D can be obtained by symmetrically turning over the third mask 150C downward. That is, it is not necessary to additionally design the patterns for the second to fourth masks 150B to 150D because the patterns for the second to fourth masks 150B to 150D can be obtained by utilizing the pattern of the first mask 150A corresponding to the ¼ field area of the image sensor.

The lithography process can be performed once. The lithography process may include the steps of forming first to fourth masks 150A to 150D, in which the second to fourth masks 150B to 150D are formed by sequentially turning over the first mask 150A upward, leftward and rightward, aligning the first to fourth masks 150A to 150D on a wafer, and exposing first to fourth dies of the wafer through the first to fourth masks 150A to 150D. The lithography process may repeat several times to form the image sensor on the wafer. Embodiments may include first to fourth dies. Thus, a large-size image sensor can be fabricated by scribing the four dies, which are aligned on the wafer in the form of the 2×2 matrix, into one cell.

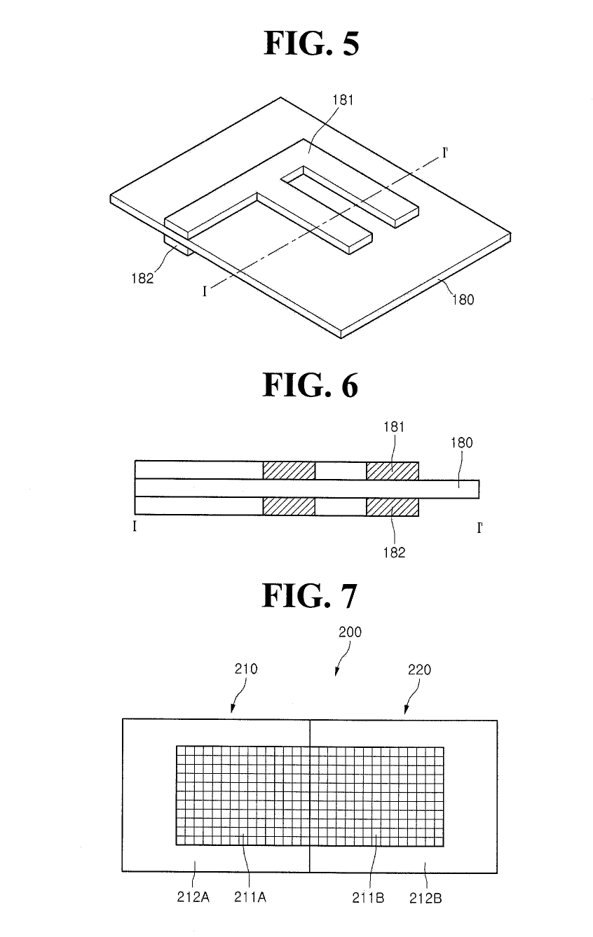

FIG. 5 is a perspective view showing another mask for manufacturing an image sensor, such as the sensor shown in FIG. 3, and FIG. 6 is a sectional view taken along line I-I′ of FIG. 5.

According to embodiments, in order to form the patterns on the first to fourth image sensing sections 110 to 140, a mask corresponding to one of the first to fourth image sensing sections 110 to 140 is primarily manufactured and masks for remaining image sensing sections are formed by sequentially turning over the mask. That is, after forming one mask, a photo process is performed by using the mask, thereby forming a large-size image sensor having patterns symmetrically inversed to each other.

Referring to FIGS. 5 and 6, a first mask pattern 181 may be formed on and/or over the top surface of a transparent quartz substrate 180 and a second mask pattern 182 may be formed at and/or over the bottom surface of the quartz substrate 180. The first mask pattern 181 and the second mask pattern 182 may include chrome or oxide chrome.

The first mask pattern 181 matches with the second mask pattern 182 when viewed from one direction. That is, the second mask pattern 182 corresponds to the first mask pattern 181. Thus, if the quartz substrate 180 is turned over, the second mask pattern 182 is positioned on the top surface of the quartz substrate 180. In this case, the second mask pattern 182 becomes a reverse pattern of the first mask pattern 181 when viewed in a plan view.

For instance, the photo process may be performed on the first image sensing section 110 by using the first mask pattern 181, and then the photo process may be performed on the third image sensing section 130 by transversely rotating the quartz substrate 180 at an angle of 180°. After that, the photo process may be performed on the second image sensing section 120 using the second mask pattern 182 by turning over the quartz substrate 180 and then the photo process may be performed on the fourth image sensing section 140 by transversely rotating the quartz substrate 180 at an angle of 180°. Therefore, when the photo process is performed by using the first mask pattern 181, the second mask pattern 182 does not exert an influence upon the photo process. In addition, when the photo process is performed using the second mask pattern 182 by turning over the quartz substrate 180, the first mask pattern 181 does not exert an influence upon the photo process.

Accordingly, a relatively large-size image sensor can be fabricated by performing the photo process four times while transversely rotating and turning over the mask. Thus, the manufacturing cost and manufacturing time for the mask can be minimized.

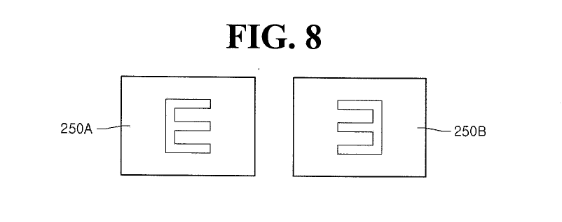

FIG. 7 is a plan view showing the image sensor according to embodiments, and FIG. 8 is a plan view showing masks for manufacturing an image sensor, such as the sensor shown in FIG. 7.

A second mask 250B can be obtained by symmetrically turning over a first mask 250A, so the manufacturing process can be simplified. The image sensor 200 can be fabricated by using two adjacent dies, so the middle-size format image sensor can be fabricated. The image sensor 200 may have various sizes. A first image sensing section 210 and a second image sensing section 220 are closely adjacent to each other at the boundary of two dies so that a first pixel array part 211A and a second pixel array part 211B may constitute one pixel array.

A first peripheral circuit part 212A, which is aligned at a peripheral portion of the first pixel array part 211A, and a second peripheral circuit part 212B, which is aligned at a peripheral portion of the second pixel array part 211B, may drive the pixel array, respectively. The ISP of the camera module can process the signals of the first and second image sensing sections 210 and 220 at a time.

Therefore, a middle-size image sensor suitable for the field size of current photo equipment can be fabricated. In addition, embodiments can provide a CMOS image sensor capable of producing a middle-size or a large-size CMOS image without exchanging expensive equipment while realizing high pixel resolution and enlarging an imaging plane. The lithography process can be performed once. The lithography process may include the steps of forming first and second masks 250A and 250B, in which the second mask 250B is formed by turning over the first mask 250A, aligning the first and second masks 250A and 250B on a wafer, and exposing first and second dies of the wafer through the first and second masks 250A and 250B. The lithography process may repeat several times to form the image sensor on the wafer and embodiments can include first and second dies.

Embodiments can provide a middle-size CMOS image sensor suitable for the available field size of conventional photo equipment, so the manufacturing cost can be minimized and price competitiveness can be maximized while providing high-quality images with high pixel resolution. According to embodiments, a middle-size format CMOS image sensor can be easily manufactured which may satisfy the demand of consumers who wish high-quality commercial pictures and products.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A device comprising:
first to fourth image sensing sections symmetrically aligned in a form of a 2×2 matrix;
first to fourth pixel arrays aligned in the first to fourth image sensing sections, respectively, substantially adjacent to each other; and
first to fourth peripheral circuit parts aligned at peripheral portions of the first to fourth image sensing sections.

2. The device of claim 1 wherein, the second to fourth image sensing sections are formed by sequentially turning over the first image sensing section.

3. The device of claim 1 wherein, the first to fourth image sensing sections are formed on four dies, respectively, which are adjacent to each other on a wafer.

4. A device comprising:
first and second image sensing sections;
first and second pixel arrays aligned adjacent to each other at a boundary between the first and second image sensing sections; and
first and second peripheral circuit parts aligned at peripheral portions of the first and second image sensing sections.

5. The device of claim 4 wherein, the second image sensing section is formed by turning over the first image sensing section.

6. The device of claim 4 wherein, the first and second sensing sections are formed on two dies, respectively, which are adjacent to each other on a wafer.

7. A method comprising:
forming first to fourth masks, in which the second to fourth masks are formed by sequentially turning over the first mask;
aligning the first to fourth masks on a wafer; and
exposing first to fourth dies, which are substantially adjacent to each other on the wafer, through the first to fourth masks.

8. The method of claim 7, comprising scribing the first to fourth dies into one cell.

9. The method of claim 7, wherein pixel array parts aligned on the first to fourth dies, respectively, are connected to each other at boundaries of the first to fourth dies.

10. The method of claim 7, wherein first to fourth peripheral circuit parts are formed at peripheral portions of the first to fourth dies.

11. A method comprising:
preparing a mask including a first mask pattern formed over a top surface of a substrate and a second mask pattern formed over a bottom surface of the substrate;
performing a first photo process on a first image sensing section by using the first mask pattern of the mask;
performing a second photo process on a third image sensing section by transversely rotating the mask at an angle of about 180°;
performing a third photo process on a second image sensing section by using the second mask pattern of the mask; and
performing a fourth photo process on a fourth image sensing section by transversely rotating the mask at an angle of about 180°.

12. The method of claim 11, wherein the first to fourth image sensing sections are aligned in a form of a 2×2 matrix, in which pixel array parts thereof are adjacent to each other.

13. The method of claim 11, wherein first to fourth peripheral circuit parts are formed at peripheral portions of the first to fourth image sensing sections, respectively.

14. A method comprising:
forming first and second masks, in which the second mask is formed by turning over the first mask;
aligning the first and second masks on a wafer; and
exposing first and second dies, which are adjacent to each other on the wafer, through the first and second masks.

15. The method of claim 14, comprising scribing the first and second dies into one cell.

16. The method of claim 14, wherein pixel array parts aligned on the first and second dies, respectively, are connected to each other at a boundary of the first and second dies.

17. The method of claim 14, wherein first and second peripheral circuit parts are formed at peripheral portions of the first and second dies.

18. A method comprising:
preparing a mask including a first mask pattern formed over a top surface of a substrate and a second mask pattern formed over a bottom surface of the substrate;
performing a first photo process on a first image sensing section by using the first mask pattern of the mask; and
performing a second photo process on a second image sensing section by using the second mask pattern of the mask.

19. The method of claim 18, wherein pixel array parts of the first and second image sensing sections are adjacent to each other.

20. The method of claim 18, wherein first and second peripheral circuit parts are formed at peripheral portions of the first and second image sensing sections, respectively.
